(19) United States
(12) Patent Application Publication
(10) Pub. No.: US 2026/0011550 A1
(43) Pub. Date: Jan. 8, 2026

(54) Selective etching of silicon nitride dielectrics with MICROWAVE oxidation

(71) Applicant: Applied Materials, Inc., Santa Clara, CA (US)

(72) Inventors: Mohammad Mahdi TAVAKOLI, Santa Clara, CA (US); Joung Joo LEE, San Jose, CA (US); Avgerinos V. GELATOS, Scotts Valley, CA (US); Bencherki MEBARKI, Santa Clara, CA (US)

(21) Appl. No.: 19/247,018

(22) Filed: Jun. 24, 2025

Related U.S. Application Data
(60) Provisional application No. 63/667,526, filed on Jul. 3, 2024.

(51) Int. Cl. H01L 21/02; H01L 21/3213

(52) U.S. Cl. CPC H01L 21/02345; H01L 21/02164; H01L 21/0217; H01L 21/02337; H01L 21/32135

(57) ABSTRACT

According to one or more embodiments, a method includes positioning a substrate within a processing chamber. The substrate includes a hardmask layer disposed over a surface of the substrate, a first layer disposed over the hardmask layer, and a second layer disposed over the first layer. The method further includes flowing a process gas into the processing chamber, and delivering a microwave energy for a period of time to the process gas to selectively etch the hardmask layer and the first layer, wherein delivering the microwave energy to the process gas does not generate a plasma.

### CROSS-REFERENCE TO RELATED APPLICATIONS

This Application claims the benefit of U.S. Provisional Patent Application Ser. No. 63/667,526 filed Jul. 3, 2024, which is hereby incorporated by reference.

### BACKGROUND

### Field

Embodiments of the present disclosure generally relate to non-plasma methods of processing a substrate. More specifically, the methods disclosed herein incorporate microwave oxidation, which can change certain material properties and/or orientation for selective etching processes.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased. Such geometry reduction has driven innovation into various etching processes to assist in the production of patterned devices.

Dry etch processes are often desirable for selectively removing material from semiconductor substrates, as these processes are capable of gently removing material from miniature structures with minimal physical disturbance. Additionally, dry etch processes have been developed to selectively remove/etch a variety of dielectrics relative to one another. However, such dry etch processes often incorporate the generation of a plasma and/or are conducted at high temperatures in the presence of halogenated process gases. Such process conditions can unintentionally and/or undesirably damage underlying layers of the semiconductor substrate.

Thus, there is a need to develop new etch processes that can selectively remove materials and minimize the amount of damage to the remaining portions of features that are exposed during the etching process.

### SUMMARY

Embodiments of the present disclosure generally relate to non-plasma methods of processing a substrate. More specifically, the methods disclosed herein incorporate microwave oxidation, which can change certain material properties and/or orientation for selective etching processes.

In some embodiments, method includes positioning a substrate within a processing chamber. The substrate includes a hardmask layer disposed over a surface of the substrate, a first layer disposed over the hardmask layer, and a second layer disposed over the first layer. The method further includes flowing a process gas into the processing chamber, and delivering a microwave energy for a period of time to the process gas to selectively etch the hardmask layer and the first layer, wherein delivering the microwave energy to the process gas does not generate a plasma.

In some embodiments, a method for etching a substrate includes positioning a substrate within a processing chamber. The substrate has a first layer disposed over a substrate surface. The first layer includes silicon dioxide (SiO₂). The substrate also has a second layer disposed over the first layer. The second layer includes a tungsten based material. The substrate also includes a feature disposed on the second layer. The feature has a first feature structure disposed on the surface of the second layer and a second feature structure disposed on the surface of the first feature structure. The substrate also includes a gapfill layer disposed over the feature and the second layer. The method further includes flowing a process gas into the processing chamber, and delivering a microwave energy to the process gas to perform an etch operation on the substrate. The etch operation selectively removes the second layer and the first feature structure.

In some embodiments, a method for etching a substrate includes positioning a substrate within a processing chamber. The substrate includes a first layer disposed over a surface of a substrate. The first layer includes a ferroelectric material. The substrate also includes a second layer disposed over the surface of a substrate. The second layer includes a non-ferroelectric material. The method further includes flowing a process gas into the processing chamber, and delivering a microwave energy to the process gas for a period of time to selectively etch the first layer. Delivering the microwave energy to the process gas does not generate a plasma.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments described herein.

FIG. 2A is a schematic of a processing chamber that includes a microwave source, in accordance with an embodiment.

FIG. 2B is a schematic of a solid state microwave emission module, in accordance with an embodiment.

FIG. 2C is a perspective view illustration of a source array for a microwave source, in accordance with an embodiment.

FIG. 2D is a cross-sectional illustration of a processing chamber for processing a substrate, in accordance with an embodiment.

FIG. 3 is a flow diagram depicts a method of processing a substrate, in accordance with an embodiment.

FIG. 4A is a cross-sectional illustration of a substrate, in accordance with an embodiment.

FIG. 4B is a cross-sectional illustration of a substrate, in accordance with an embodiment.

FIG. 4C is a cross-sectional illustration of a substrate, in accordance with an embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the present disclosure generally relate to a selective etching process that utilizes microwave enhanced non-plasma processing methods for processing a substrate. The methods disclosed herein may include positioning a substrate into a processing chamber, flowing a process gas into the processing chamber, and delivering an amount of microwave energy at a microwave frequency to the process gas to perform an etch operation on the substrate without generating a plasma. The lack of plasma generation allows for compositionally selective etching without the potential to damage underlying films. More specifically, in one or more embodiments of the disclosure, the methods provided herein incorporate a microwave oxidation, which can change certain material properties and/or orientation of atoms within the exposed material to enable a selective etching process. For instance, microwave oxidation of certain materials having high dielectric constants (e.g., SiN) can promote their transition to a metastable phase, which can be removed/etched from the substrate via sublimation. Such processes disclosed herein provide compositionally selective etching through differences in material properties and/or the material's response to microwave oxidation conditions.

### Processing System Example

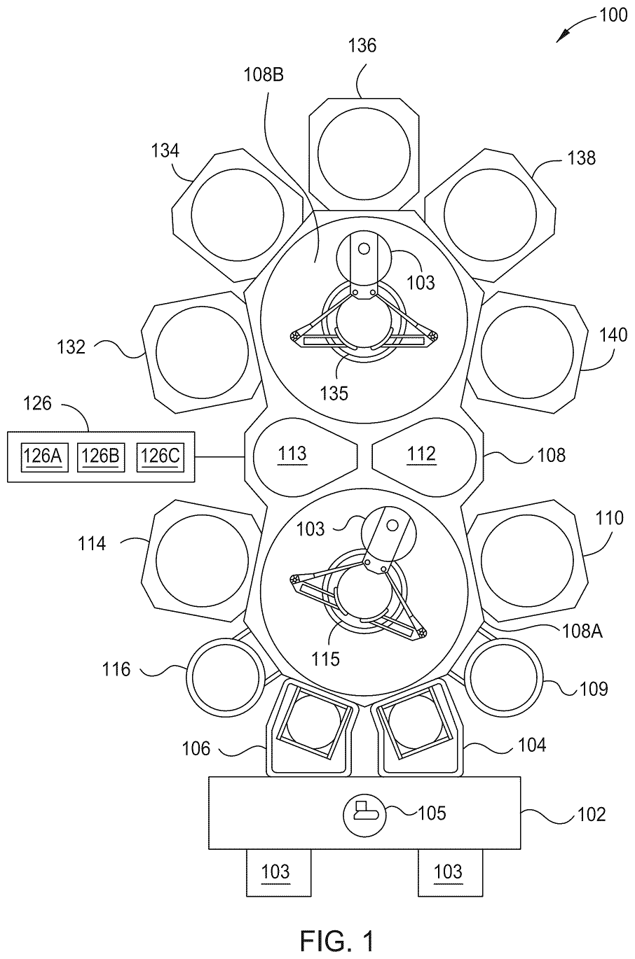

FIG. 1 illustrates a schematic representation of a processing system 100 for use with one or more embodiments of the disclosure. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 mTorr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura®, Producer® or Centura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the substrate processing system 100 (also referred to as a “processing platform”), according to embodiments described herein. The substrate processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described further below, in one or more embodiments of the substrate processing sequence described herein, all of the processes are performed under vacuum within the processing system 100. In one example of the processing system 100, a remote-plasma-source (RPS) cleaning process is performed in chamber 110, a precleaning process is performed in chamber 114, and one or more of a deposition, an etching, and/or a thermal processing process is performed in at least one of the chambers 132, 134, 136, 138, and 140. In one example, the remote plasma (RPS) assisted process performed in chamber 110 is performed in a processing chamber, such as Aktiv™ Preclean (APC) chamber available from Applied Materials of Santa Clara, Calif. In another example, the processing chambers 132, 134, 136, 138, or 140 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the chambers 110 and 114, and one or more of a deposition, an etching, and/or a thermal processing process is performed in at least one of the chambers 132, 134, 136, 138, and 140. In one example, the processing chambers 132, 134, 136, 138, or 140 may be a Volta™ CVD/ALD chamber, or Encore™ PVD chambers available from Applied Materials of Santa Clara, Calif.

### Processing Chamber Example

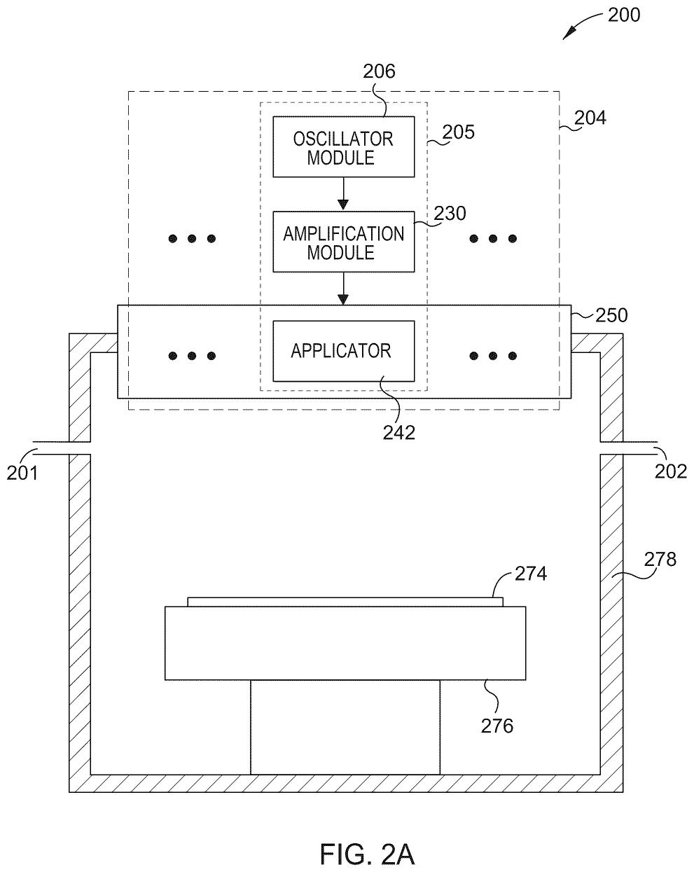

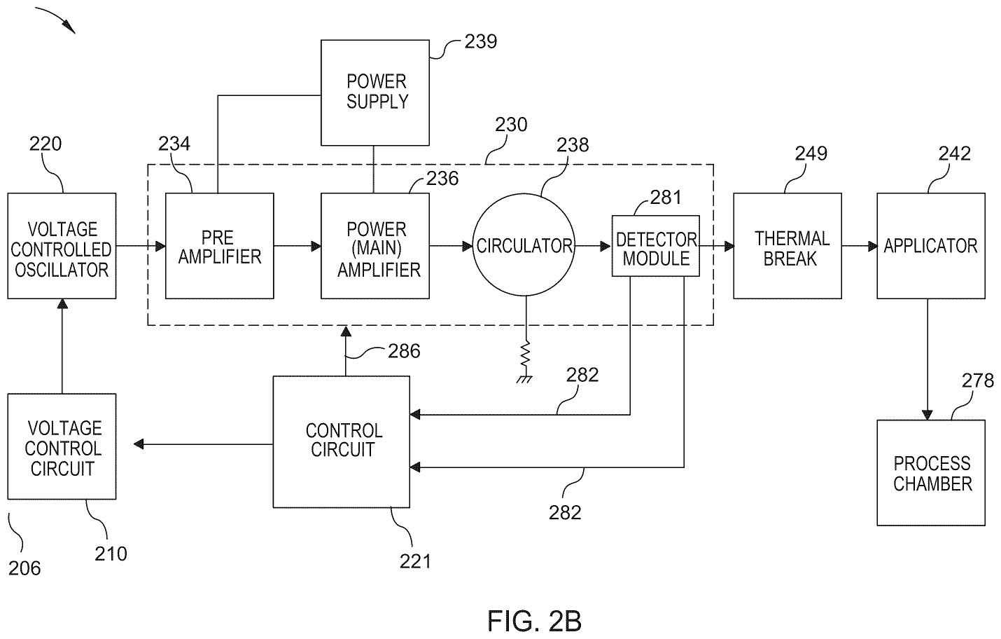

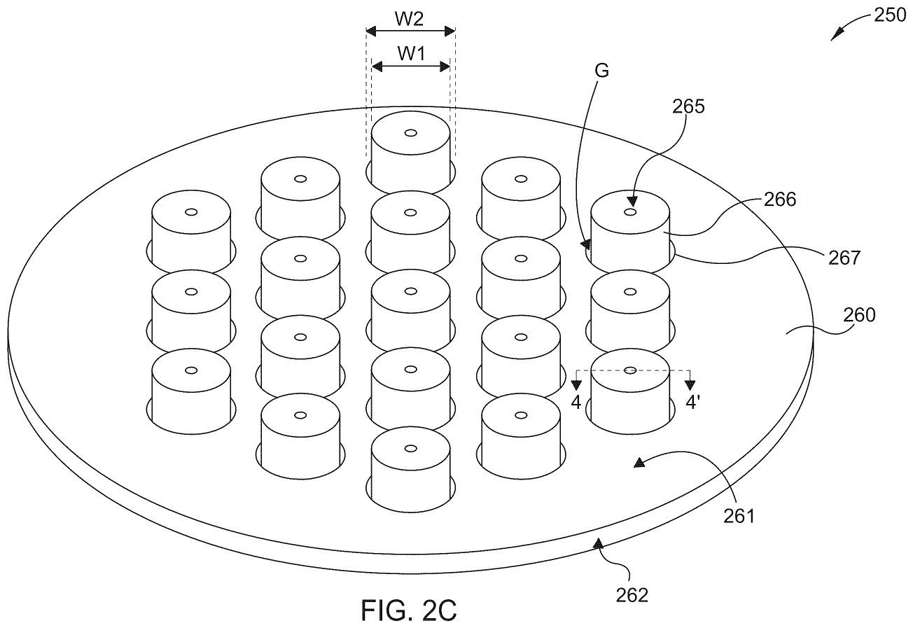

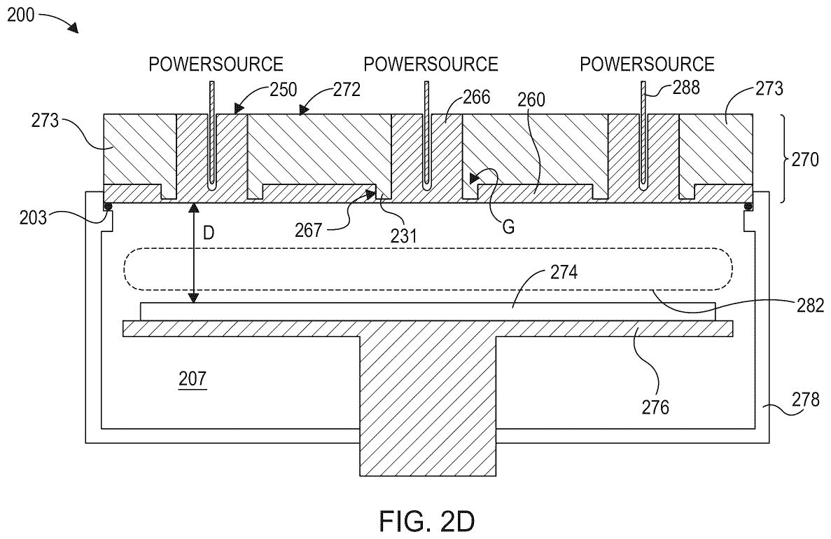

Referring now to FIGS. 2A-2D, a series of illustrations depicting an example of a microwave processing tool 200 is shown, in accordance with an embodiment. The microwave processing tool 200 is configured to deliver microwave energy to a processing region of the process chamber to perform a selective etching process on a substrate, which can be performed at a desired processing temperature.

Referring now to FIG. 2A, a cross-sectional illustration of a microwave processing tool 200 (referred to as processing tool 200 for short) is shown, according to an embodiment. In some embodiments, the processing tool 200 may be a processing tool suitable for any type of processing operation that requires the delivery of microwave energy. In some embodiments, one or more of the chambers 110 and 114, or even chambers 132-140, may include the processing tool 200. The processing tool may emit high-frequency electromagnetic radiation in the form of microwave energy. In some embodiments, “High-frequency” may refer to frequencies between 300 MHz and 1000 GHz. In some embodiments, the high-frequency electromagnetic radiation is provided at frequencies in the “S-band”, such as frequencies between about 2.4 GHz and about 2.6 GHz.

Generally, embodiments include a processing tool 200 that includes a chamber 278. In processing tool 200, the chamber 278 may be a vacuum chamber. A vacuum chamber may include a pump (not shown) for removing gases from the chamber to provide the desired vacuum. Additional embodiments may include a chamber 278 that includes one or more gas lines 201 for providing processing gasses into the chamber 278 and exhaust lines 202 for removing byproducts from the chamber 278. While not shown, it is to be appreciated that gas may also be injected into the chamber 278 through a source array 250 (e.g., as a showerhead) for evenly distributing the processing gases over a substrate 274.

In an embodiment, the substrate 274 may be supported on a chuck 276. For example, the chuck 276 may be any suitable chuck, such as an electrostatic chuck. The chuck 276 may also include cooling lines and/or a heater to provide temperature control to the substrate 274 during processing. Due to the modular configuration of the high-frequency emission modules described herein, embodiments allow for the processing tool 200 to accommodate any sized substrate 274. For example, the substrate 274 may be a semiconductor wafer (e.g., 200 mm, 300 mm, 450 mm, or larger). Alternative embodiments also include substrates 274 other than semiconductor wafers. For example, embodiments may include a processing tool 200 configured for processing glass substrates, (e.g., for display technologies).

According to an embodiment, the processing tool 200 includes a modular high-frequency emission source 204. The modular high-frequency emission source 204 may comprise an array of high-frequency emission modules 205. In an embodiment, each high-frequency emission module 205 may include an oscillator module 206, an amplification module 230, and an applicator 242. As shown, the applicators 242 are schematically shown as being integrated into the source array 250.

In an embodiment, the oscillator module 206 and the amplification module 230 may comprise electrical components that are solid state electrical components. In an embodiment, each of the plurality of oscillator modules 206 may be communicatively coupled to different amplification modules 230. For example, each oscillator module 206 may be electrically coupled to a single amplification module 230. In an embodiment, the plurality of oscillator modules 206 may generate incoherent electromagnetic radiation. Accordingly, the electromagnetic radiation induced in the chamber 278 will not interact in a manner that results in an undesirable interference pattern.

In an embodiment, each oscillator module 206 generates high frequency electromagnetic radiation that is transmitted to the amplification module 230. After processing by the amplification module 230, the electromagnetic radiation is transmitted to the applicator 242. In an embodiment, the applicators 242 each emit electromagnetic radiation into the chamber 278. In some embodiments, the applicators 242 couple the electromagnetic radiation to the processing gasses in the chamber 278 to provide energy thereto, without forming a plasma.

Referring now to FIG. 2B, a schematic of a solid state high-frequency emission module 205 is shown, in accordance with an embodiment. In an embodiment, the high-frequency emission module 205 comprises an oscillator module 206. The oscillator module 206 may include a voltage control circuit 210 for providing an input voltage to a voltage controlled oscillator 220 in order to produce high-frequency electromagnetic radiation at a desired frequency. The voltage controlled oscillator 220 is an electronic oscillator whose oscillation frequency is controlled by the input voltage. According to an embodiment, the input voltage from the voltage control circuit 210 results in the voltage controlled oscillator 220 oscillating at a desired frequency.

According to an embodiment, the electromagnetic radiation is transmitted from the voltage controlled oscillator 220 to an amplification module 230. The amplification module 230 may include a driver/pre-amplifier 234, and a main power amplifier 236 that are each coupled to a power supply 239. According to an embodiment, the amplification module 230 may operate in a pulse mode. For example, the amplification module 230 may have a duty cycle between 1% and 99%. In a more particular embodiment, the amplification module 230 may have a duty cycle between approximately 15% and 50%.

In an embodiment, the electromagnetic radiation may be transmitted to the thermal break 249 and the applicator 242 after being processed by the amplification module 230. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. It is to be appreciated that the detector module 281 may be located at one or more different locations in the system (e.g., between the circulator 238 and the thermal break 249). In an embodiment, the control circuit module 221 interprets the forward power 283 and the reflected power 282, and determines the level for the control signal 285 that is communicatively coupled to the oscillator module 206 and the level for the control signal 286 that is communicatively coupled to the amplification module 230. In an embodiment, control signal 285 adjusts the oscillator module 206 to optimize the high-frequency radiation coupled to the amplification module 230. In an embodiment, control signal 286 adjusts the amplification module 230 to optimize the output power coupled to the applicator 242 through the thermal break 249. In an embodiment, the feedback control of the oscillator module 206 and the amplification module 230, in addition to the tailoring of the impedance matching in the thermal break 249, may allow for the level of the reflected power to be less than approximately 5% of the forward power. In some embodiments, the feedback control of the oscillator module 206 and the amplification module 230 may allow for the level of the reflected power to be less than approximately 2% of the forward power.

Accordingly, embodiments allow for an increased percentage of the forward power to be coupled into the processing chamber 278, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

Referring now to FIG. 2C, a perspective view illustration of a source array 250 is shown, in accordance with an embodiment. In an embodiment, the source array 250 comprises a dielectric plate 260. A plurality of cavities 267 are disposed into a first surface 261 of the dielectric plate 260. The cavities 267 do not pass through to a second surface 262 of the dielectric plate 260. The source array 250 may further include a plurality of dielectric resonators 266. Each of the dielectric resonators 266 may be in a different one of the cavities 267. Each of the dielectric resonators 266 may comprise a hole 265 in the axial center of the dielectric resonator 266.

In an embodiment, the dielectric resonators 266 may have a first width W1, and the cavities 267 may have a second width W2. The first width W1 of the dielectric resonator 266 is smaller than the second width W2 of the cavities 267. The difference in the widths provides a gap G between a sidewall of the dielectric resonators 266 and a sidewall of the cavity 267. In the illustrated embodiment, each of the dielectric resonators 266 are shown as having a uniform width W1. However, it is to be appreciated that not all dielectric resonators 266 of a source array 250 need to have the same dimensions.

Referring now to FIG. 2D, a cross-sectional illustration of a processing tool 200 that includes an assembly 270 is shown, in accordance with an embodiment. In an embodiment, the processing tool comprises a chamber 278 that is sealed by an assembly 270. For example, the assembly 270 may rest against one or more O-rings 203 to provide a vacuum seal to an interior chamber volume 207 of the chamber 278. In other embodiments, the assembly 270 may interface with the chamber 278. That is, the assembly 270 may be part of a lid that seals the chamber 278. In an embodiment, the processing tool 200 may comprise a plurality of processing volumes (which may be fluidically coupled together), with each processing volume having a different assembly 270. In an embodiment, a chuck 279 or the like may support a substrate 274. The substrate 274 may be a distance D from the assembly 270. In an embodiment, the interior chamber volume 207 may be suitable for delivering microwave energy to a process gas disposed within the chamber 278. That is, the chamber 278 may be a vacuum chamber.

In an embodiment, the assembly 270 comprises a source array 250 and a housing 272. The source array 250 may comprise a dielectric plate 260 and a plurality of dielectric resonators 266 extending up from the dielectric plate 260. Cavities 267 into the dielectric plate 260 may surround each of the dielectric resonators 266. Sidewalls of the cavity 267 are separated from the sidewall of the dielectric resonator 266 by a gap G. The dielectric plate 260 and the dielectric resonators 266 of the source array 250 may be a monolithic structure (as shown in FIG. 2D), or the dielectric plate 260 and the dielectric resonators 266 may be discrete components.

The housing 272 include rings 231 that fit into the gaps G. In an embodiment, the rings 231 and the conductive body 273 of the housing 272 are a monolithic structure (as shown in FIG. 2D), or the conductive body 273 and the rings 231 may be discrete components. The housing 272 may having openings sized to receive the dielectric resonators 266. In an embodiment, monopole antennas 288 may extend into holes in the dielectric resonators 266. The monopole antennas 288 are each electrically coupled to power sources (e.g., high-frequency emission modules 205).

### Substrate Processing Sequences

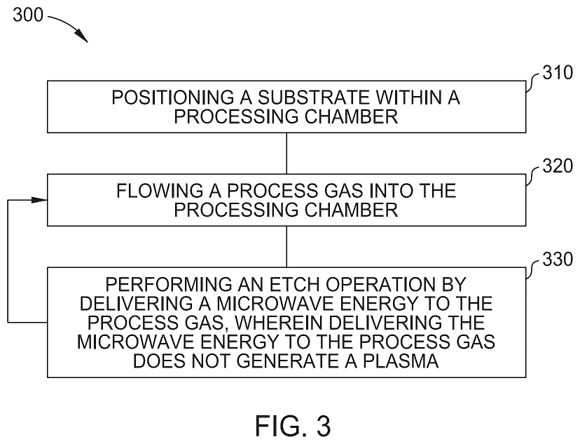

FIG. 3 depicts a process flow diagram of a method 300 of processing a substrate to, for example, form middle-of-line (MOL) and back-end-of-line (BEOL) structures, according to one or more embodiments of the present disclosure. The method 300 includes positioning a substrate within a processing chamber (operation 310), flowing a process gas into the process chamber (operation 320), delivering a microwave energy to the flowing process gas to perform an etch operation on the substrate (operation 330). In some embodiments, operation 330 of the method 300 may include pulsing the delivery of the microwave energy in a sequence that has a duty cycle of between 1% and 99%, such as between 20% and 80%. The pulsing process is performed while the process gas is flowing and until the selective etching process removes a desired amount of material from the substrate. The processes performed during operation 330 will include the delivery of the microwave energy at a power level that does not generate a plasma in the processing region over the surface of the substrate, which can be verified by use of various metrology techniques that can include the use of a Langmuir probe or optical detection technique. Substrates of the present disclosure may include one or more layers and/or features formed from one or more dielectric, gapfill, or hardmask materials.

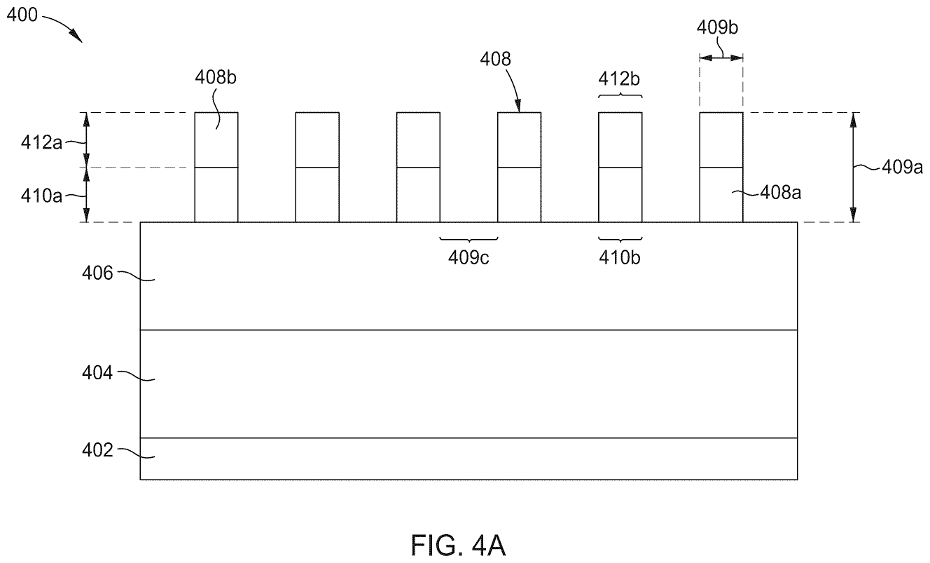

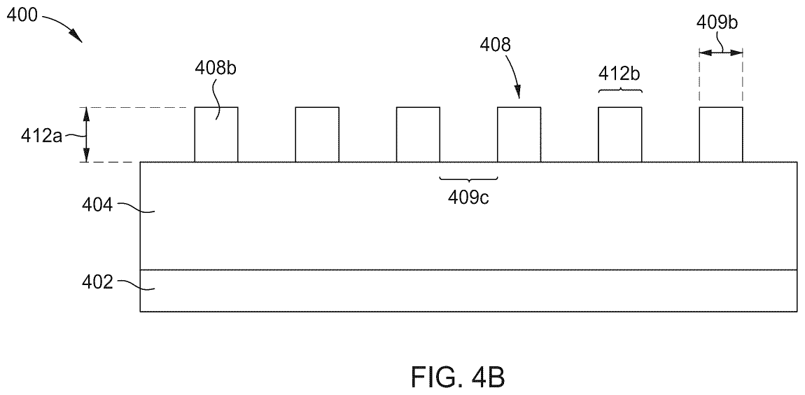

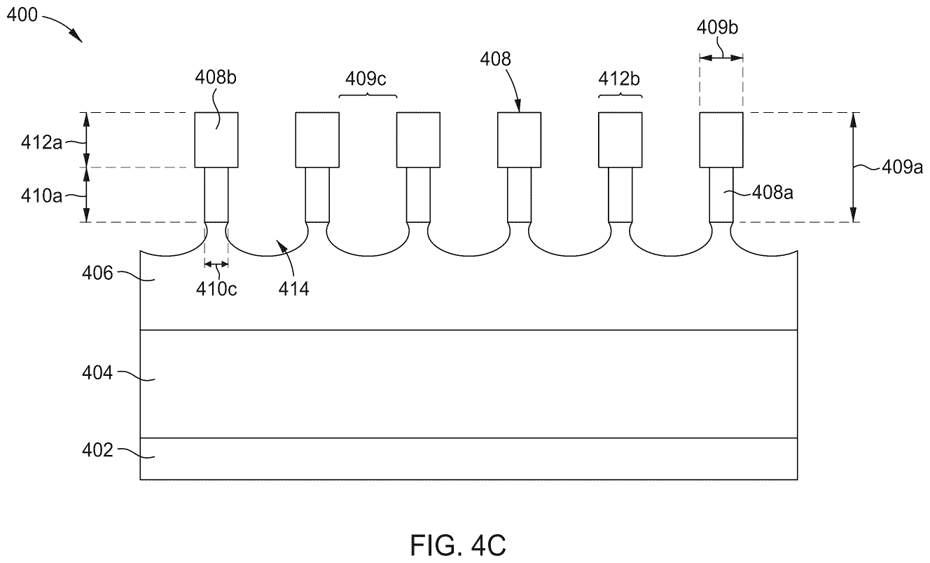

FIG. 4A depicts a substrate 400 prior to undergoing to the method 300. The substrate 400 may include a silicon dioxide (SiO₂) layer 404 deposited on a substrate surface 402. The SiO₂ layer 404 may include a thickness of about 50 nm to about 200 nm. The substrate 400 may also include a hardmask layer 406 deposited over the SiO₂ layer 404. The hardmask layer 406 may include a carbon, metal or metal oxide layer that can include one or more tungsten (W) based materials (such as tungsten carbide (WC)), one or more titanium based materials, one or more zinc based materials, one or more perovskite structured materials (e.g., BaTiO₃/SrTiO₃), one or more materials having a high dielectric constant under microwave applied oxygen (O₂) gas, and combinations thereof. The substrate 400 may also include one or more features 408 deposited over the surface of the hardmask layer 406. The one or more features 408 of the substrate 400 may include one or more layers (e.g., 408a and 408b) disposed in a stack formation. The one or more layers (e.g., 408a and 408b) may independently include one or more dielectric materials, such as silicon oxide (SiOx), silicon nitride (SiNx), silicon oxycarbide (SiOC), silicon oxynitride (SiON), one or more low-dielectric constant materials, and combinations thereof.

In at least one embodiment, a substrate 400 has a hardmask layer 406 having tungsten (W) and at least one feature 408 having a first layer 408a disposed over the hardmask layer 406 and a second layer 408b disposed over the first layer 408a. In one example, the first layer 408a may include SiNₓ, and the second layer 408b may include SiOₓ. In at least one embodiment, the feature 408 may have a feature height 409a of about 10 nm to about 200 nm and a feature width 409b of about 10 nm to about 100 nm. In at least one embodiment, a substrate 400 has two or more features 408 separated by a spacing distance 409c of about 5 nm to about 50 nm. In at least one embodiment, the first layer 408a of the feature 408 has a height 410a of about 10 nm to about 100 nm and a width 410b of about 10 nm to about 100 nm. In at least one embodiment, the second layer 408b of the feature 408 has a height 412a of about 10 nm to about 100 nm and a width 412b of about 10 nm to about 100 nm.

Referring back to method 300 of FIG. 3, operation 310 includes positioning a substrate (e.g., substrate 400) in a processing chamber. At operation 320, a process gas is flowed into the processing chamber. The process gas may include one or more oxygen based process gases, such as O₂ gas, ozone, and combinations thereof and a fluorine-based chemistry such as hydrogen, nitrogen, or carbon containing halogens, such as HF, NF₃, CF₄, C₃F₈, or CHF₃. In at least one embodiment, the process gas includes O₂ gas. The process gas may be flowed into the processing chamber at a flow rate of about 1 sccm to about 10 sccm. In one or more embodiments, the process gas may include O₂ that is flowed into the processing chamber at a flow rate of about 1 sccm to about 10 sccm and/or a fluorine based chemistry flowed into the processing chamber at a flow rate of about 1 sccm to about 5 sccm.

At operation 330, an etch operation is performed on the substrate 400 by providing a microwave energy to the process gas for a period of time. The etch operation of operation 330 is conducted without the generation of a plasma. In some embodiments, the lack of generated electromagnetic radiation at frequencies not provided to the processing region of the process chamber, such as wavelengths in the visible region, can be used to detect that a plasma has not been formed within the processing region. In at least one embodiment, the temperature within the processing chamber during operation 330 may be maintained at about 0° C. to about 500° C., such as about 10° C. to about 400° C., such as about 20° C. to about 350° C., alternatively about 100° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 500° C. In at least one embodiment, the pressure within the processing chamber (i.e., the chamber pressure) during operation 330 is about 1 mTorr to about 12 m Torr, such as about 1 mTorr to about 8 mTorr.

In at least one embodiment, the microwave energy applied to the process gas during operation 330 (the delivered microwave energy) is about 25 W to about 150 W, such as about 25 W to about 125 W per resonator. In some embodiments, the dielectric plate 260 can include 10 to 25 resonator 266, such as between about 15 and 20 resonators. In one example, the total power provided to the process gas is between about 250 W and 3200 W, such as between 1000 W and 3000 W. In some embodiments, the microwave energy is provided at frequencies in the “S-band”, such as frequencies between about 2.4 GHz and about 2.6 GHZ, such as about 2.45 GHz. The microwave energy may be applied to the process gas for a period of time of about 30 s to about 10 min, such as about 2 min to about 8 min, such as about 4 min to about 6 min, alternatively about 1 min to about 2 min, alternatively about 2 min to about 4 min, alternatively about 4 min to about 5 min, alternatively about 5 min to about 6 min, alternatively about 6 min to about 8 min, alternatively about 8 min to about 10 min, alternatively about 2 min to about 5 min.

In one or more embodiments, to conduct the etch operation of operation 330 without the generation of a plasma a ratio of the microwave energy to the chamber pressure is less than 3000:1 (W/mTorr). In one or more embodiments, the ratio of the microwave energy to the chamber pressure is from about 198:1 (W/mTorr) to about 3000:1 (W/mTorr).

In at least one embodiment, the processing chamber is purged after operation 330 to remove one or more contaminants therefrom. In at least one embodiment, operation 320 and 330 are cyclically performed to produce a layer-by-layer etch operation. In such instances, operations 320 and 330 may be cyclically performed for 1 cycle to about 50 cycles, such as about 1 cycle to about 25 cycles, such as about 1 cycle to about 10 cycles. As noted above, in some embodiments, operation 330 of the method 300 may include pulsing the delivery of the microwave energy in a sequence that has a duty cycle of between 1% and 99%, such as between 20% and 80%. The pulsing process is performed while the process gas is flowing and until the selective etching process removes a desired amount of material from the substrate

FIG. 4B depicts the substrate 400 after undergoing the processing operations of the method 300. The substrate 400 may include a SiO₂ layer 404 deposited on a substrate surface 402, a second layer 408b deposited over the SiO₂ layer. In at least one embodiment, the SiO₂ layer 404 may include a thickness of about 50 nm to about 200 nm after undergoing the processing operations of the method 300. In at least one embodiment, the second layer 408b of the feature 408 has a height 412a of about 10 nm to about 100 nm and a width 412b of about 10 nm to about 100 nm after undergoing the processing operations of the method 300.

In at least one embodiment, the thickness SiO₂ layer 404 after undergoing the processing operations of the method 300 is substantially similar to the thickness SiO₂ layer 404 before undergoing the processing operations of the method 300. In at least one embodiment, the height 412a and width 412b of the second layer 408b of the feature 408 after undergoing the processing operations of the method 300 is substantially similar to the height 412a and width 412b of the second layer 408b of the feature 408 before undergoing the processing operations of the method 300.

As illustrated in FIG. 4B, the method 300 disclosed herein offers compositionally selective etch operation. By comparing the substrate 400 in FIG. 4B with the substrate 400 in FIG. 4A, it can be observed that the processing operations of the method 300 can selectively etch the hardmask layer 406 (which includes tungsten) and the first layer 408a (e.g., SiN layer) of the feature 408 without damaging and/or etching the remaining layers of the substrate, such as the second layer 408b (e.g., SiOx layer). Without being bound by theory, SiN and/or tungsten interacts with the O₂ gas (introduced at operation 320) when a microwave energy is applied thereto (applied at operation 330). This interaction changes the SiₓN_{y} stoichiometry (e.g., the formation of a SiₓN_{y}/SiₓN_{y}O_{z} compound) resulting in the formation of an unstable phase having ferroelectric properties and the generation of high localized heat on a microscopic scale due to exposure to the microwave energy. The unstable SiₓN_{y} phase and/or the tungsten hardmask layer will sublimate under at least the microwave power and low pressure conditions previously described for the method 300. As a result, the unstable SiₓN_{y} phase and/or the tungsten hardmask layer are selectively etched from the substrate 400, which, for example, includes a silicon oxide (SiOx) layer. Furthermore, the SiO₂ layer 404, and the second layer 408b of the feature 408 remain after the method 300 since the material compositions used to prepare such layers and structures do not interact with the O₂ gas under the application of a microwave energy. In addition, the method 300 does not incorporate or form a plasma which alleviates and/or eliminates potentially damaging and/or etching of the SiO₂ layer 404, and the second layer 408b of the feature 408.

Overall, the methods disclosed herein provide compositionally selective substrate etching methods using microwave energy. The methods disclosed herein do not incorporate the use and/or generation of a plasma, which allows for etch selectivity without the potential to damage underlying films. While FIGS. 4A and 4B illustrate the complete removal of the hardmask layer 406 and the first layer 408a by use of method 300, in some embodiments, the methods provided herein can be used to selectively partially etch portions of layered structures (e.g., exposed portions of the substrate 400) as desired by changing the period of time.

FIG. 4C. depicts the substrate 400 after undergoing the processing operations of the method 300. In one or more embodiments, as noted above, by controlling the period of time, the hardmask layer 406 and the first layer 408a can be partially etched with selectivity to the second layer 408b. Stated, differently, the etch rate of the hardmask layer 406, the first layer 408a, and the second layer 408b are different, with the etch rate of the second layer 408b being less than the etch rates of the hardmask layer 406 and the first layer 408a. Therefore, as illustrated in FIG. 4C, the width of the first layer 408a is reduced from the width 410b (FIG. 4A) to the width 410c. Furthermore, as illustrated in FIG. 4A portions 414 of the hardmask layer 406 (i.e., exposed portions of the hardmask layer 406) are also partially etched. For example, the methods disclosed herein can be used to at least partially etch the silicon nitride portions of a multi-layer ONO stack used in NAND or DRAM structures to form recesses in the SiN layers that have a desired depth.

It is believed that the processes described herein can be used to selectively etch materials that exhibit ferroelectric properties (e.g., SiNₓ, aluminum nitride (AlN), perovskite materials, hydrofluoroolefins (HfOx), HZO) versus materials that do not exhibit ferroelectric properties (e.g., SiOₓ).

While the foregoing is directed to embodiments of the present disclosure, other and further embodiments of the disclosure may be devised without departing from the basic scope thereof, and the scope thereof is determined by the claims that follow.

We claim:

1. A method comprising:
positioning a substrate within a processing chamber, the substrate comprising:
a hardmask layer disposed over a surface of the substrate;
a first layer disposed over the hardmask layer; and
a second layer disposed over the first layer;
flowing a process gas into the processing chamber; and
delivering a microwave energy for a period of time to the process gas to selectively etch the hardmask layer and the first layer, wherein delivering the microwave energy to the process gas does not generate a plasma.

2. The method of claim 1, wherein the process gas comprises a fluorine-based chemistry and oxygen (O₂) gas.

3. The method of claim 1, wherein the hardmask layer comprises tungsten carbide (WC).

4. The method of claim 1, wherein the first layer comprises silicon nitride (SiNₓ) and the second layer comprise silicon oxide (SiOₓ).

5. The method of claim 2, wherein the O₂ gas is flowed into the processing chamber at a flow rate of about 1 sccm to about 10 sccm, the fluorine-based chemistry is flowed into the processing chamber at a flow rate of about 1 sccm to about 5 sccm, a temperature of the processing chamber is maintained at about 0° C. to about 500° C., and a pressure within the processing chamber is about 1 mTorr to about 12 mTorr.

6. The method of claim 1, wherein a ratio of the delivered microwave energy to a pressure within the processing chamber is less than about 3000:1.

7. The method of claim 1, wherein ratio of the delivered microwave energy to a pressure within the processing chamber is from about 198:1 to about 3000:1.

8. The method of claim 1, wherein the period of time is about 0.1 min to about 5 min.

9. A method comprising:
positioning a substrate within a processing chamber, the substrate comprising:
a first layer disposed over a surface of the substrate, the first layer comprising silicon dioxide (SiO₂),
a second layer disposed over the first layer, the second layer comprising a tungsten based material, and
a feature disposed on the second layer, the feature having a first feature structure disposed on the surface of the second layer and a second feature structure disposed on the surface of the first feature structure;
flowing a process gas into the processing chamber; and
delivering a microwave energy to the process gas to perform an etch operation on the substrate, wherein the etch operation selectively removes the second layer and the first feature structure.

10. The method of claim 9, wherein delivering the microwave energy to the process gas does not generate a plasma.

11. The method of claim 9, wherein the process gas comprises a fluorine-based chemistry and oxygen (O₂) gas.

12. The method of claim 11, wherein the O₂ gas is flowed into the processing chamber at a flow rate of about 1 sccm to about 10 sccm, the fluorine-based chemistry is flowed into the processing chamber at a flow rate of about 1 sccm to about 5 sccm, a temperature of the processing chamber is maintained at about 0° C. to about 500° C., and a pressure within the processing chamber is about 1 mTorr to about 12 mTorr.

13. The method of claim 9, wherein a ratio of microwave energy applied to the process gas to perform the etch operation to a pressure within the processing chamber is less than about 3000:1.

14. The method of claim 9, wherein a ratio of microwave energy applied to the process gas to perform the etch operation to a pressure within the processing chamber is from about 198:1 to about 3000:1.

15. The method of claim 9, wherein the second layer comprises tungsten carbide (WC), the first feature structure comprises silicon nitride (SiNₓ), and the second feature structure comprises silicon oxide (SiOₓ).

16. A method comprising:
positioning a substrate within a processing chamber, the substrate comprising:
a first layer disposed over a surface of the substrate, the first layer comprising a ferroelectric material,
a second layer disposed over the surface of the substrate, the second layer comprising a non-ferroelectric material,
flowing a process gas into the processing chamber; and
delivering a microwave energy to the process gas for a period of time to selectively etch the first layer, wherein delivering the microwave energy to the process gas does not generate a plasma.

17. The method of claim 16, wherein the first layer comprises SiNₓ, aluminum nitride (AlN), perovskite materials, hydrofluoroolefins (HfOx), or HZO.

18. The method of claim 16, wherein a ratio of the delivered microwave energy to a pressure within the processing chamber is less than about 3000:1.

19. The method of claim 16, wherein a ratio of the delivered microwave energy to a pressure within the processing chamber is from about 198:1 to about 3000:1.

20. The method of claim 16, wherein the first layer further comprises a high dielectric material and the second layer further comprises a low dielectric material.
